(19) United States
(12) Patent Application Publication
(10) Pub. No.: US 2023/0112982 A1
(43) Pub. Date: Apr. 13, 2023

(54) DISPLAY PANEL AND DISPLAY DEVICE

(71) Applicant: WUHAN TIANMA MICROELECTRONICS CO., LTD., Wuhan (CN)

(72) Inventor: Chunming JIN, Wuhan (CN)

(73) Assignee: WUHAN TIANMA MICROELECTRONICS CO., LTD., Wuhan (CN)

(21) Appl. No.: 18/064,415

(22) Filed: Dec. 12, 2022

(30) Foreign Application Priority Data
Jun. 14, 2022 (CN) 202210669476.9

(51) Int. Cl. H10K 59/126; H10K 59/40; H10K 77/10; H10K 50/844

(52) U.S. Cl. CPC H01L 27/3272; H01L 27/323; H01L 51/0097; H01L 51/5253; H01L 2251/5338

(57) ABSTRACT

A display panel and a display device. The display panel includes a display area and a non-display area, a substrate and a conductive structure located on one side of the substrate. The conductive structure is located in the non-display area, and at least part of an edge of the conductive structure away from the display area overlaps a cutting edge of the substrate in a direction perpendicular to a plane of the substrate.

### CROSS REFERENCE TO RELATED APPLICATIONS

The present application claims priority to Chinese Patent Application No. CN 202210669476.9, filed on Jun. 14, 2022, the content of which is incorporated herein by reference in its entirety.

### TECHNICAL FIELD

The application relates to the field of display technologies, and in particular to a display panel and a display device.

### BACKGROUND

Organic light-emitting Diodes (OLED) have the advantage of self-emission, with no need to set an additional light source, which is conducive to the overall thinness and lightness of the display device. In addition, organic self-emitting display technology has the advantages of fast response, wide viewing angle, high brightness and low power consumption, which has become a focus of current research. The organic light-emitting diode can be manufactured on a flexible substrate, which achieves the production of flexible display devices. At present, the flexible OLED display panel has the problem of illumination at the edge of the display area.

### SUMMARY

This disclosure provides a display panel and a display device to reduce the risk of illumination at the edge of the display area.

In a first aspect, an embodiment of the present disclosure provides a display panel having a display area and a non-display area; wherein the display panel comprises a substrate and a conductive structure on a side of the substrate, the conductive structure is located on the non-display area; and at least part of an edge of the conductive structure away from the display area overlaps a cutting edge of the substrate in a direction perpendicular to a plane of the substrate.

In a second aspect, based on the same inventive concept, an embodiment of the present disclosure also provides a display device, including a display panel provided by any embodiment of the application.

### BRIEF DESCRIPTION OF DRAWINGS

In order to more clearly explain the embodiments of the present disclosure or the technical solution in the related art, the drawings used in the description of the embodiments or the related art will be briefly described below. The drawings in the following description are some embodiments of the present disclosure. Those skilled in the art can obtain other drawings based on these drawings without creative efforts.

FIG. 1 is a schematic diagram of a display panel according to an embodiment of the present disclosure.

FIG. 2 is a cross-sectional diagram at line A-A′ in FIG. 1.

FIG. 3 is a schematic diagram of another display panel according to an embodiment of the present disclosure;

FIG. 4 is another cross-sectional diagram at line A-A′ in FIG. 1.

FIG. 5 is another cross-sectional diagram at line A-A′ in FIG. 1.

FIG. 6 is another cross-sectional diagram at line A-A′ in FIG. 1.

FIG. 7 is another cross-sectional diagram at line A-A′ in FIG. 1.

FIG. 8 is another cross-sectional diagram at line A-A′ in FIG. 1.

FIG. 9 is a schematic diagram of another display panel according to an embodiment of the present disclosure.

FIG. 10 is a cross-sectional diagram along line C-C′ in FIG. 9.

FIG. 11 is a schematic diagram of another display panel according to an embodiment of the present disclosure.

FIG. 12 is another cross-sectional diagram at line A-A′ in FIG. 1.

FIG. 13 is another cross-sectional diagram along line C-C′ in FIG. 9.

FIG. 14 is another cross-sectional diagram at line A-A′ in FIG. 1.

FIG. 15 is a schematic diagram of another display panel according to an embodiment of the present disclosure.

FIG. 16 is a schematic diagram of another display panel according to an embodiment of the present disclosure.

FIG. 17 is a schematic diagram of another display panel according to an embodiment of the present disclosure.

FIG. 18 is a partial schematic diagram of another display panel according to an embodiment of the present disclosure.

FIG. 19 is another cross-sectional diagram at line A-A′ in FIG. 1.

FIG. 20 is another cross-sectional diagram at line A-A′ in FIG. 1.

FIG. 21 is a schematic diagram of another display panel according to an embodiment of the present disclosure.

FIG. 22 is a schematic diagram of a display device according to an embodiment of the present disclosure.

### DETAILED DESCRIPTION

In order to better understand technical solutions of the present disclosure, the embodiments of the present disclosure are described in detail with reference to the drawings. It should be clear that the described embodiments are merely part of the embodiments of the present disclosure rather than all of the embodiments. It is obvious for those skilled in the art that other embodiments made based on the embodiments of the present disclosure fall within the protection scope of the present disclosure.

The terms used in the embodiments of the present disclosure are merely for the purpose of describing specific embodiment, rather than limiting the present disclosure. The terms “a”, “an”, “the”, and “said” in a singular form in the embodiments of the present disclosure and the attached claims are also intended to include plural forms thereof, unless noted otherwise.

Electrostatic charge may be generated on the surface of the display in use due to friction, and the static electricity can be conducted to the cutting edge of the substrate through an edge of the cover plate. However, large amount of charge accumulated on an cutting edge of the substrate may not disappear, which may form an electric field, and then affect the pixels adjacent to the cutting edge, and lead to the problem of illumination at the edge of the display area.

In order to solve the above problem, an embodiment of the present disclosure provides a display panel, and a conductive structure is set in the non-display area of the display panel to shield the static electricity, and conduct and disperse the static electricity to prevent the local accumulation of static electricity, and thereby preventing static electricity from accumulating and not dissipating at the cutting edge of the substrate, and affecting pixels adjacent to the cutting edge, thus improving the illumination phenomenon at the edge of the display area.

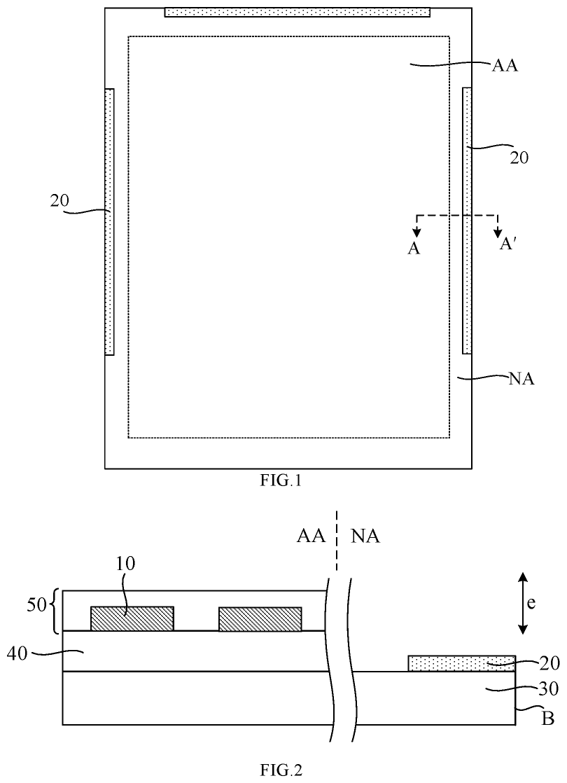

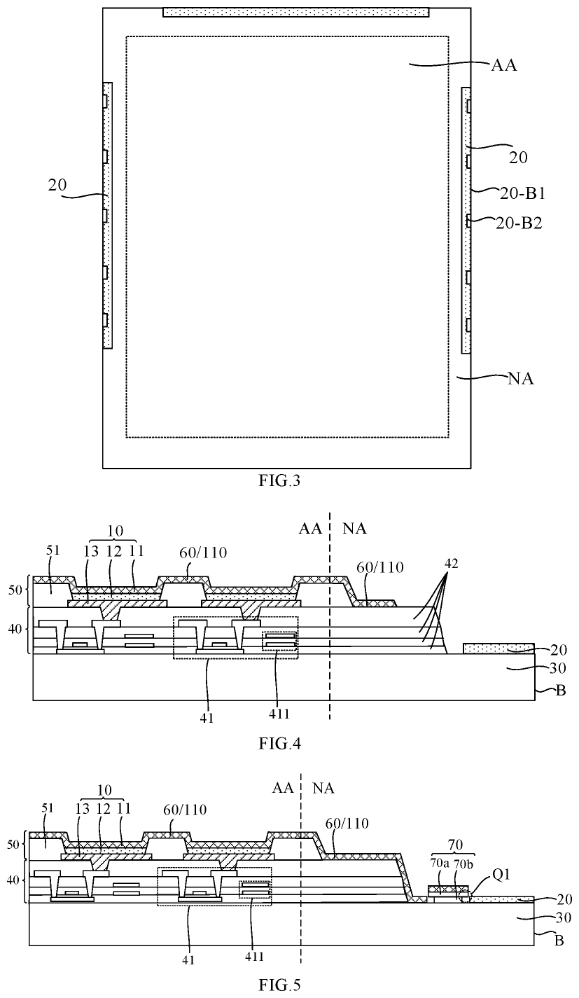

FIG. 1 is a schematic diagram of a display panel according to an embodiment of the present disclosure. FIG. 2 is a cross-sectional diagram at line A-A′ in FIG. 1. FIG. 3 is a schematic diagram of another display panel according to an embodiment of the present disclosure.

As shown in FIG. 1, the display panel includes display area AA and non-display area NA, the non-display area NA surrounds the display area AA; the display area AA includes light emitting devices (not shown in FIG. 1), and the non-display area NA is provided with a conductive structure 20.

As shown in FIG. 2, display panel includes a substrate 30, an array layer 40, and a display layer 50. A light emitting device 10 is located on the display layer 50, and the light emitting device 10 is an organic light-emitting diode or an inorganic light-emitting diode. Array layer 40 includes pixel circuits for driving the light emitting device 10 to emit light. The conductive structure 20 is located on one side of the substrate 30. As shown in FIG. 2, an edge of the conductive structure 20 away from the display area AA is flush with a cutting edge B of the substrate 30, and the conductive structure 20 has conductive properties. In view of FIG. 1 and FIG. 2, along a direction perpendicular to a plane of the substrate 30, an edge of one side the conductive structure 20 away from the display area AA overlaps a cutting edge B of the substrate 30.

In another embodiment, as shown in the top view of FIG. 3, the edge of one side the conductive structure 20 away from the display area AA includes a first edge 20-B1 and a second edge 20-B2, in the direction perpendicular to the plane of the substrate 30, the first edge 20-B1 overlaps the cutting edge B of the substrate 30, and the second edge 20-B2 does not overlap the cut edge B of the substrate 30, that is, in the embodiment of FIG. 3, part of the edge of one side of the conductive structure 20 away from the display area AA overlaps the cut edge B of the substrate 30. In other words, along the direction perpendicular to the plane of the substrate 30, viewing from the conductive structure 20 to the substrate 30, the conductive structure 20 is able to cover at least part of the edge area of the substrate 30. The top view shape of the conductive structure 20 in FIG. 1 and FIG. 3 is only shown schematically and is not used to limit the present disclosure. As long as in the direction perpendicular to the plane of the substrate 30, at least part of the edge of the conductive structure 20 away from the display area AA overlaps the cutting edge B of the substrate 30, the technical solution falls within the scope of the present disclosure.

The substrate 30 is a flexible substrate. The flexible substrate may be formed by polymer materials such as polyimide (PI), polycarbonate (PC), polyethersulfone (PES), polyethylene terephthalate (PET), polyethylene naphthalate (PEN), polyarylate (PAR) or glass fiber reinforced plastic (FRP).The flexible substrate may be transparent, semitransparent or nontransparent. The substrate 30 is used to carry the display layer 50, array layer 40 and other structures in the display panel. It is understood that the substrate 30 includes the portion located in the display area AA and the portion located in the non-display area NA. The cutting edge B of the substrate 30 is understood to be an end edge of the substrate 30. A display panel motherboard is firstly fabricated when starting fabrication, and then the motherboard is cut along a preset cutting line to form a plurality of individual display panel. The cutting edge B of the substrate 30 is the edge formed after cutting the motherboard during fabrication. When fabricating the display panel provided by an embodiment of the present disclosure, a conductive part is fabricated near the preset cutting line, part of the conductive part overlaps the preset cutting line, and the conductive part is cut at the same time when cutting along the preset cutting line. In other words, the conductive part is cut with the substrate 30, and the conductive part left on the display panel after cutting forms a conductive structure 20 such that at least part of the conductive structure 20 away from the edge of the display area AA is flush with the cutting edge B of the substrate 30. That is, at least part of the edge of the conductive structure 20 away from the display area AA overlaps the cutting edge B of the substrate 30.

In the display panel provided by an embodiment of the present disclosure, the conductive structure 20 is arranged in the non-display area BA, the conductive structure 20 and light emitting device 10 are on the same side of the substrate 30, and at least part of the edge of the conductive structure 20 away from one side of the display area AA overlaps the cutting edge B of the substrate 30, the conductive structure 20 is able to cover at least part of the edge area of the substrate 30 on a side of the substrate adjacent to the display layer 50. Electrostatic charge generated on the surface of the display panel in use may firstly enter the conductive structure 20, in this way, the conductive structure 20 can prevent the electrostatic charge from entering the substrate 30 through the cutting edge of the substrate 30, and conduct and disperse the electrostatic charge to prevent the local accumulation of the electrostatic charge, and prevent electrostatic charge from accumulating at the cutting edge of the substrate 30 and not dissipating, thus affecting pixels adjacent to the cutting edge B, thereby improving the illumination phenomenon at the edge of the display area.

In some embodiments, FIG. 4 is another cross-sectional diagram at line A-A′ in FIG. 1. As shown in FIG. 4, the display panel includes a functional structure 60 located on the same side as the conductive structure 20 on the substrate 30, and at least part of the functional structure 60 is located in the display area AA; conductive structure 20 and the functional structure 60 are made of the same material. Functional structure 60 is the original structure in the display panel.

The material of conductive structure 20 is the same as the material of functional structure 60, and the conductive structure 20 can be made in the same process with functional structure 60, which can simplify the fabricating process.

In an embodiment of the disclosure, as shown in FIG. 4, the conductive structure 20 is not connected to the functional structure 60. In other words, the conductive structure 20 and functional structure 60 are not physically connected. In this way, the setting of the conductive structure 20 can avoid adverse effects of the functional structure 60 on the function of the functional structure 60 or on the display function.

In one embodiment, as shown in FIG. 4, the functional structure 60 includes a first electrode layer 110. The light emitting device 10 in the display area AA includes a first electrode 11, a light emitting layer 12 and a second electrode 13 that are stacked. Multiple first electrodes 11 are connected to each other to form the first electrode layer 110; The first electrode layer 110 extends from the display area AA to the non-display area NA. The light emitting device 10 is located in the display layer 50, the display layer 50 also includes a pixel-defined layer 51, and the pixel-defined layer 51 is used to separate adjacent light emitting devices 10. The array layer 40 includes the pixel circuit 41. A transistor in the pixel circuit 41 and the pixel capacitor 411 are also shown in FIG. 4 in a simplified way. The pixel circuit 41 is connected to the second electrode 13, and the second electrode 13 is a reflection electrode, the first electrode 11 is a transmission electrode. The first electrode layer 110 extends from the display area AA to the non-display area NA, and the first electrode layer 110 in the non-display area NA is not in direct contact with the conductive structure 20. In this embodiment, the conductive structure 20 can be fabricated in the same process as the first electrode layer 110. The conductive structure 20 is used to transfer the charge into the conductive structure 20 to prevent the electrostatic charge from entering the substrate 30. In the embodiment of the present disclosure, the conductive structure 20 can conduct and disperse the electrostatic charge to prevent local accumulation of the electrostatic charge, and prevent the electrostatic charge from accumulating at the cutting edge of the substrate 30 and not dissipating, and affecting the pixels adjacent to the cutting edge B, thereby improving the phenomenon of illumination at the edge of the display area.

In addition, a fabrication material of the first electrode layer 110 includes metal oxides with high light transmittance. The first electrode layer 110 has good conductive property and corrosion resistance. The conductive structure 20 and the first electrode layer 110 are made of the same fabrication material, then the conductive structure 20, which is flush with the cutting edge of the substrate 30, is not easily corroded by water and oxygen although the conductive structure 20 is exposed, which ensures the stable performance of the conductive structure 20. In addition, the conductive structure 20 may be cut together with the substrate 30 during fabrication. The conductive structure 20 and the first electrode layer 110 are configured to made of the same material can make the conductive structure 20 thinner, and the cutting process requires less cutting energy, which can improve the cutting accuracy.

In the embodiment of the present disclosure, at least part of the edge of a side of the conductive structure 20 away from the display area AA is flush with the cutting edge B of the substrate 30, in other words, at least part of the edge of a side of the conductive structure away from the display area AA overlaps the cutting edge B of the substrate 30 in a direction perpendicular to a plane of the substrate 30, then, at least part of the edge of structure 20 may be exposed and in contact with water and oxygen in the air. In the embodiment where the conductive structure 20 has the same material as the first electrode layer 110 and the conductive structure 20 disposed in the non-display area NA is not in contact with the first electrode layer 110, water and oxygen intrusion path can be blocked, thereby preventing water and oxygen from entering the first electrode layer 110 through the conductive structure 20, and thus affecting the service life of light emitting device 10 in display area AA.

In some embodiments, the second electrode 13 includes a reflective layer and a metal oxide layer that are stacked, the material of the reflective layer includes at least one of Ag, Mg, Al, Pt, Pd, Au, Ni, Nd, Ir, or Cr, and the material of metal oxide layer includes at least one of indium tin oxide, indium zinc oxide, zinc oxide, or indium oxide. The material of the first electrode 11 includes at least one of indium tin oxide, indium zinc oxide, zinc oxide, or indium oxide.

In some embodiments, FIG. 5 is another cross-sectional diagram at line A-A′ in FIG. 1. As shown in FIG. 5, the non-display area NA includes the partition structure 70, the conductive structure 20 and the first electrode layer 110 are disconnected at the position of the partition structure 70. The first electrode layer 110 extends from the display area AA to the non-display area NA. The first electrode layer 110 is a continuous structure of the whole layer, therefore, the mask used in the production of the first electrode layer 110 is a public mask, and the opening of the public mask plate requires forming of a whole large area of the first electrode layer 110. In the partition structure 70 of the present embodiment, the film material during fabrication may naturally break at the position of partition structure 70, such that the first electrode layer 110 and the conductive structure 20 that are fabricated in the same layer and with the same material is not connected to each other. During fabrication, the partition structure 70 is used to partition the first electrode layer 110 and the conductive structure 20, such that the first electrode layer 110 and the conductive structure 20 are not connected, ensuring that the performance of the first electrode layer 110 may not be affected, and at the same time, the accuracy requirement of the mask plate used in the production of the first electrode layer 110 can be decreased, which is beneficial to reduce the production cost.

FIG. 5 illustrates a partition structure 70, as shown in FIG. 5, the partition structure 70 includes a first subpart 70a and a second subpart 70b. An edge of the first subpart 70a extends out of an edge of the second subpart 70b to form a step, and the step is shown at position Q1 in FIG. 5. The first subpart 70a and the second subpart 70b are stacked to form a similar “T” shape structure to partition the first electrode layer 110 and the conductive structure 20 fabricated in the same process. The partition structure 70 in FIG. 5 is only illustrative and does not limit the present application.

In another embodiment, FIG. 6 is another cross-sectional diagram at line A-A′ in FIG. 1. As shown in FIG. 6, the partition structure 70 includes the first metal portion 71, and an end of the first metal portion 71 adjacent to the display area AA is in contact with the first electrode layer 110, and an end of the first metal portion 71 away from the display area AA is in contact with the conductive structure 20. In this embodiment, the partition structure 70 is used to partition the first electrode layer 110 and the conductive structure 20 to block the path of water and oxygen invading through the conductive structure 20 to the first electrode layer 110. The conductive structure 20 located in the non-display area NA can prevent electrostatic charge from entering the substrate 30, and the conductive structure 20 is electrically connected to the first electrode layer 110 by the first metal portion 71 in the partition structure 70, and the electrostatic charge in the conductive structure 20 can be transferred into the first electrode layer 110 for dispersion, so as to prevent local accumulation of electrostatic charge, and improve the illumination phenomenon at the edge of the display area.

In other words, in the embodiment of FIG. 6, the partition structure 70 can not only physically partition and disconnect the first electrode layer 110 and the conductive structure 20, but also electrically connect the conductive structure 20 and the first electrode layer 110 by using the metal portion in the partition structure 70.

As shown in FIG. 6, the partition structure also includes a second metal portion 72 and a middle portion 73. The middle portion 73 is located on a side of the first metal portion 71 away from the substrate 30, and the second metal portion 72 is located on a side far of the middle portion 73 away from the first metal portion 71. In particular, the second metal portion 72 extends out of the edge of the middle portion 73 to form a step (this step can be understood with reference to the step in FIG. 5). In this embodiment, the conductive structure 20 located in the non-display area NA can prevent the electrostatic charge from entering the substrate 30, so as to prevent the electrostatic charge entering the substrate 30 from affecting the pixels at the edge of the display area AA. Moreover, the first electrode layer 110 and the conductive structure 20 are physically separated by the step formed by the second metal portion 72 and the middle portion 73, so as to block the path of water and oxygen invading the first electrode layer 110 through the conductive structure 20. At the same time, the first metal portion 71 can be used to realize the electrical connection between the conductive structure 20 and the first electrode layer 110, such that the electrostatic charge of the conductive structure 20 can be transferred into the first electrode layer 110 for dispersion, thereby preventing local accumulation of electrostatic charge, and improving the illumination phenomenon at the edge of the display area.

In an embodiment, the middle portion 73 is made of metal materials. In one embodiment, the material of the first metal portion 71 and the second metal portion 72 includes the metal titanium, and the material of the middle portion 73 includes the metal aluminum. The partition structure 70 can be fabricated by reusing original metal layer of the display panel, thus simplifying the process.

In some embodiments, the array layer 40 includes a semiconductor layer, a first metal layer, a second metal layer, a third metal layer, and a fourth metal layer on one side of substrate 30 away from substrate 30 sequentially. An insulating layer is also provided between the semiconductor layer and the first metal layer and between the two adjacent metal layers. An active layer of the transistor in the pixel circuit is located in a semiconductor layer, and data lines, scanning lines, light emitting control lines, reset signal lines and power lines in the display panel are respectively arranged in the first metal layer, the second metal layer, the third metal layer and the fourth metal layer. In one embodiment, the first metal layer and the second metal layer are made of metal molybdenum, the fourth metal layer and the third metal layer are made of metal titanium and metal aluminum, both the fourth metal layer and the third metal layer have a titanium/aluminum/titanium three-layer metal structure. Optionally, the partition structure 70 is fabricated in the same process as the fourth or third metal layer.

In other embodiments, the array layer 40 includes a semiconductor layer, a first metal layer, a second metal layer, and a third metal layer on one side of the substrate 30 away from the substrate 30 sequentially. An insulating layer is also arranged between the semiconductor layer and the first metal layer and between the two adjacent metal layers. The active layer of the transistor in the pixel circuit is located in the semiconductor layer, and the data lines, scanning lines, light emitting control lines, reset signal lines and power lines in the display panel are respectively set in the first metal layer, the second metal layer and the third metal layer. The first metal layer and the second metal layer are made of metal molybdenum, the third metal layer is made of metal titanium and metal aluminum, and the third metal layer has a titanium/aluminum/titanium three-layer metal structure.

In other embodiments, the partition structure 70 includes inorganic materials or organic materials. The partition structure 70 is made of insulating materials, and the partition structure 70 has a step structure similar to that shown in FIG. 5, such that the first electrode layer 110 and the conductive structure 20 can be partitioned by the partition structure 70.

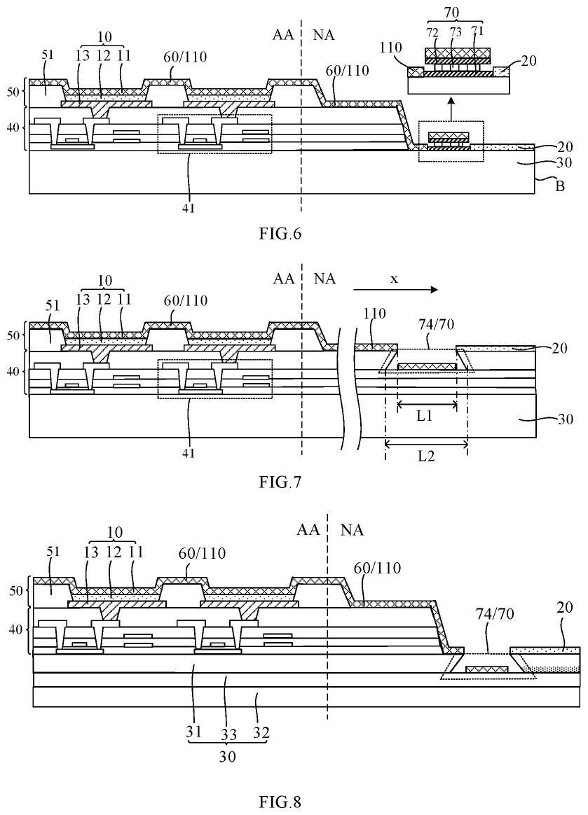

In some embodiments, FIG. 7 is another cross-sectional diagram at line A-A′ in FIG. 1. As shown in FIG. 7, the partition structure 70 includes a groove 74, and the groove 74 includes a groove bottom and a notch. In the direction X pointing from the display area AA to the cutting edge B, a length of the notch L1 is smaller than a length of the groove bottom L2. In the cross-sectional diagram, the groove 74 has a trapezoidal-like shape, and an area of the groove bottom of the groove 74 is larger than an area of notch. In this embodiment, the conductive structure 20 can be fabricated in the same process as the first electrode layer 110, and the film material at the groove 74 may be deposited at the groove bottom. Due to the special shape of the groove 74, no film material may be deposited on the groove wall of groove 74, such that the film material at the groove bottom and the film material on both sides of the notch may be discontinuous.

In some embodiments, the array layer 40 includes insulating layers, the insulating layer in the array layer 40 extends from the display area AA to the non-display area NA. At least one insulating layer in the array layer 40 is used to make a groove 74 to achieve the partition between the first electrode layer 110 and the conductive structure 20.

In other embodiments, the pixel-defined layer 51 extends from the display area AA to the non-display area NA, and the groove 74 is made with the pixel-defined layer 51 to achieve the partition between the first electrode layer 110 and the conductive structure 20, and related figures are omitted here.

In another embodiment, FIG. 8 is another cross-sectional diagram at line A-A′ in FIG. 1. As shown in FIG. 8, the groove 74 is located on the substrate 30. In this embodiment, a groove 74 is made on the substrate 30 to partition the first electrode layer 110 from the conducting structure 20.

As shown in FIG. 8, substrate 30 includes a first flexible substrate 31 and a second flexible substrate 32 that are stacked. The first flexible substrate 31 is located on a side of the second flexible substrate 32 adjacent to array layer 40. A barrier layer 33 is also arranged between the first flexible substrate 31 and the second flexible substrate 32, and the groove 74 penetrates through the first flexible substrate 31. In prior art, it is usually necessary to fabricate the display panel on the rigid substrate. After the production of the display panel, the display panel and the rigid substrate may be partitioned, which may cause some damage to the substrate of the display panel during the partition. In the embodiment of the present disclosure, the substrate 30 includes a first flexible substrate 31 and a second flexible substrate 32, which can improve the yield of the partition process between the display panel and the rigid substrate. In addition, the first flexible substrate 31 adjacent to the side of the array layer 40 is used to make the groove 74, and the first electrode layer 110 is partitioned from the conductive structure 20 by the groove 74, at the same time, the overall mechanical stability of the substrate 30 can also be ensured.

In some embodiments, the barrier layer 33 is an insulating layer, and the barrier layer 33 includes at least one of silicon nitride, silicon oxide, or silicon oxynitride. The material of the first flexible substrate 31 is the same as that of the second flexible substrate 32.

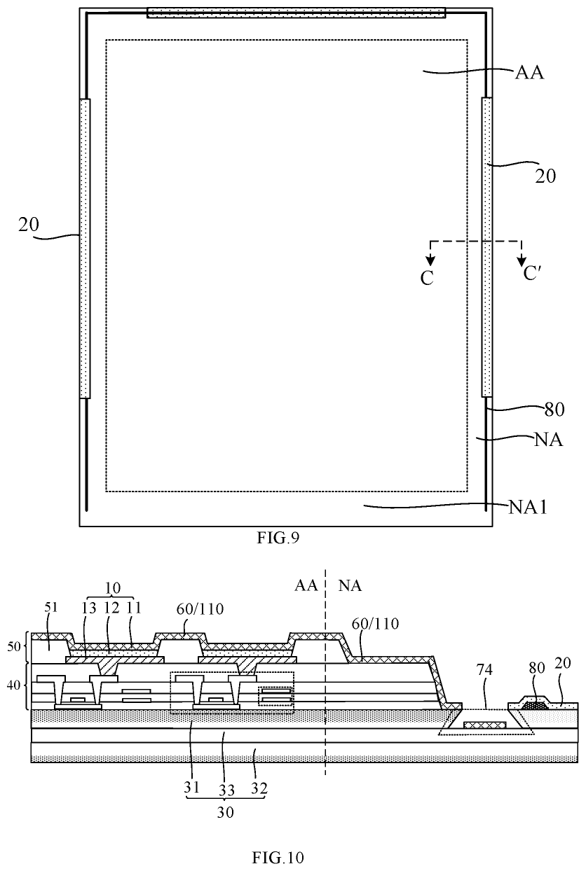

In another embodiment, FIG. 9 is a schematic diagram of another display panel according to an embodiment of the present disclosure, FIG. 10 is a cross-sectional diagram at line C-C′ in FIG. 9. As shown in FIG. 9, a metal wire 80 is disposed in the non-display area NA. The metal wire 80 is arranged to surround at least half of the display area AA, and the conductive structure 20 is connected to the metal wire 80. As shown in FIG. 10, the metal wire 80 is located on a side of groove 74 away from the display area AA, and the conductive structure 20 is connected to the metal wire 80. In an embodiment, the conductive structure 20 covers a side of the metal wire 80 away from the substrate 30. In this embodiment, the metal wire 80 conduct and disperse the electrostatic charge of the conductive structure 20 to prevent local accumulation of electrostatic charge, thereby improving the illumination phenomenon at the edge of the display area.

In some embodiments, the metal wire 80 is floating, or the metal wire 80 is connected to a fixed potential to conduct and disperse the electrostatic charge of the conductive structure 20 with the metal wire 80.

In an embodiment, as shown in FIG. 10, the non-display area NA further includes a first non-display area NA1, and pads are arranged in the first non-display area NA1 (not shown in FIG. 10), the pad are used to bind flexible circuit boards or driver chips.

The metal wire 80 is routed in the non-display area NA and extends to the first non-display area NA1. In an embodiment, the metal wire 80 is connected to the pad that provides a fixed potential in the first non-display area NA1.

In some embodiments, FIG. 11 is a schematic diagram of another display panel according to an embodiment of the present disclosure, as shown in FIG. 11, the display panel comprises an encapsulation layer 90, and the encapsulation layer 90 is located on a side of the light emitting device 10 away from the substrate 30, and an edge of the encapsulation layer 90 is located in the non-display area AA. The partition structure 70 is located on a side of the encapsulation layer 90 away from the display area AA. The encapsulation layer 90 can be used to block water and oxygen to protect the light emitting device 10 in the display area AA. The conductive structure 20 and the first electrode layer 110 are fabricated in the same process, and the conductive structure 20 and the first electrode layer 110 are partitioned by the partition structure 70 which is disposed on an external side of the encapsulation layer 90, so as to block the path of water and oxygen invading the first electrode layer 110 through the conductive structure out of the encapsulation layer 90, thereby ensuring the packaging reliability.

In the embodiment of the present disclosure, the encapsulation layer 90 includes at least one inorganic layer and at least one organic layer. As shown in FIG. 10, the encapsulation layer 90 includes a first inorganic layer 91, an organic layer 92 and a second inorganic layer 93. In the non-display area NA, the first barrier wall 94 and the second barrier wall 95 are provided and the height of the first barrier wall 94 is lower than the height of the second barrier wall 95. An edge of the package layer 90 is located on a side of the second barrier wall 95 away from the display area AA.

In some embodiments, a partition structure is also provided between the edge of the encapsulation layer 90 and the display area AA, that is, a partition structure is provided within the packaging area to further block water and oxygen from entering the display area AA through the first electrode layer 110.

In some embodiments, the mask used to fabricate the first electrode layer 110 can be designed, and the mask includes a first opening and a second opening, and the first opening is used to fabricate the first electrode layer 110, and the second opening is used to fabricate the conductive structure 20. By designing the mask, the first electrode layer 110 and conductive structure 20 which are not connected can be fabricated at the same time in a process, and there may not be an additional partition structure in the display panel, which simplifies the production process of the display panel.

In another embodiment, FIG. 12 is another cross-sectional diagram at line A-A′ in FIG. 1. As shown in FIG. 12, the display panel includes a power structure 010 located in the non-display area AA. An edge of the first electrode layer 110 is connected to the power structure 010, and the power structure 010 and the second electrode 13 are located on the same layer. An end of conductive structure 20 adjacent to the display area AA is connected to the power structure 010.

In this embodiment, no partition structure is set between the first electrode layer 110 and the conductive structure 20, and different openings on the mask can be used to fabricate the first electrode layer 110 and the conductive structure 20 respectively, such that the first electrode layer 110 and the conductive structure 20 are not connected. The first electrode layer 110 is connected to the power structure 010 which provides a constant power supply voltage for the first electrode layer 110 when the display panel is in operation. In this embodiment, the conductive structure 20 is set to be connected to the power supply structure 010, such that the electrostatic charge accumulated on the conductive structure 20 can be transferred into the power supply structure 010 and dispersed, thereby avoiding the local accumulation of electrostatic charge.

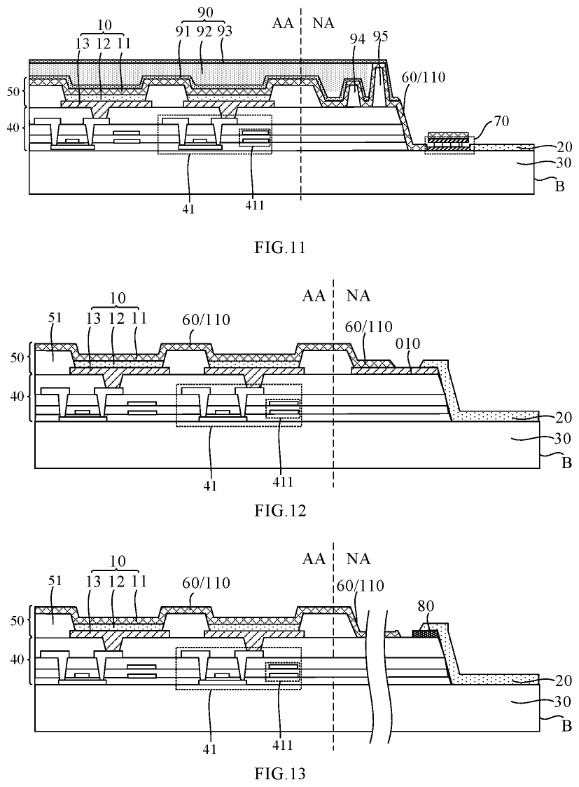

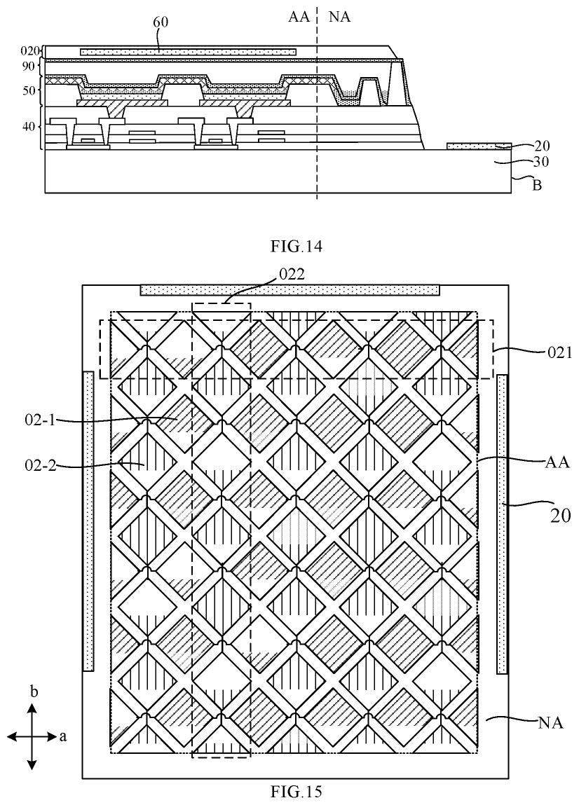

In some embodiments, FIG. 13 is another cross-sectional diagram along line C-C′ in FIG. 9. As shown in FIG. 13, the first electrode layer 110 is not connected to the conductive structure 20, and no partition structure is set between the first electrode layer 110 and the conductive structure 20. During fabrication, different openings on the mask can be used to fabricate the first electrode layer 110 and the conductive structure 20 respectively, such that the first electrode layer 110 and the conductive structure 20 are not connected. In addition, the conductive structure 20 is connected to the metal wire 80 in the non-display area NA. The conductive structure 20 can block at least part of the edge area of a side of the substrate 30 adjacent to the display layer 50, and the electrostatic charge firstly enters into the conductive structure, so as to prevent the electrostatic charge from entering into the substrate 30. In this embodiment, a metal wire 80 can also be used to conduct and disperse the electrostatic charge on the conductive structure 20 to prevent local accumulation of electrostatic charge, thereby improving illumination phenomenon at the edge of the display area.

In some embodiments, the metal wire 80 is a crack detection line, which is used to detect the whether there are cracks in the non-display area NA.

In some embodiments, the metal wire 80 is an electrostatic protection line and the metal wire 80 is grounded.

In some embodiments, the first non-display area NA1 shown in FIG. 9 is provided with a constant voltage terminal, and the constant voltage terminal provides constant voltage signal, the conductive structure 20 is connected to the constant voltage terminal, and there is a constant potential on the conductive structure 20 which can not only transfer the electrostatic charge into the conductive structure 20, but also disperse the electrostatic charge, and prevent local accumulation of the electrostatic charge.

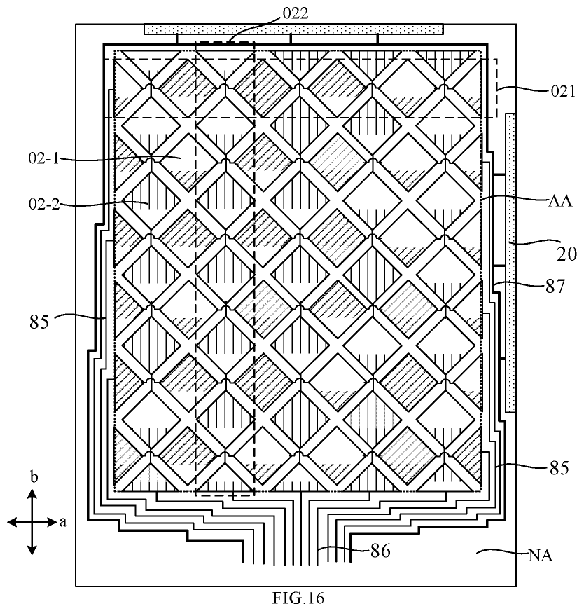

In another embodiment, FIG. 14 is another cross-sectional diagram at line A-A′ in FIG. 1. As shown in FIG. 14, the display panel also includes a touch control layer 020, the touch control layer 020 is located on a side of the encapsulation layer 90 away from the display layer 50, and the touch control layer 020 includes the functional structure 60. The material of conductive structure 20 is the same as that of functional structure 60, and conductive structure 20 is not in contact with functional structure 60. The conductive structure 20 is fabricated in the same process as the functional structure 60 in the touch control layer 020. For example, the functional structure 60 can be a touch control electrode or a touch control line in the touch control layer 020. The structure in the touch control layer 020 is usually fabricated by an etching process. The mask used in the etching process is a high accuracy mask, such that the production accuracy can be ensured and the conductive structure 20 and the functional structure 60 fabricated at the same time are not connected to each other. The conductive structure 20 is used to shield the electrostatic charge from entering the substrate 30. Moreover, the setting of conductive structure 20 does not affect the performance of functional structure 60 in the touch control layer 020.

In some embodiments, FIG. 15 is a schematic diagram of another display panel according to an embodiment of the present disclosure, as shown in FIG. 15, the touch control layer 020 includes first electrode blocks 02-1 and second electrode blocks 02-2 located in the display area AA. The first electrode blocks 02-1 arranged along a first direction a is connected with each other to form a first touch control electrode 021, and the second electrode blocks 02-2 arranged along a second direction b is connected with each other to form a second touch control electrode 022. Two adjacent first electrode blocks 02-1 on the first direction a are connected through a first connection part (not shown in FIG. 15), and the two adjacent second electrode blocks 02-2 on a second direction b are connected through a second connection part (not shown in FIG. 15), and the first connection part and the second connection part are insulated and crossed to each other. One of the first connection part and the second connection part is located in the same layer with the electrode block. The display panel also includes the touch control line (not shown in FIG. 15), the touch control line includes a first touch control line and a second touch control line. The first touch control line is connected to the first touch control electrode 021, and the second touch control line is connected to the second touch control electrode 022. The touch control layer 020 includes a first touch control conduction layer and a second touch control conduction layer. The first electrode block 02-1 and the second electrode block 02-2 are located in the first touch control conduction layer. One of the first connection part and the second connection part is located in the first touch control conduction layer and the other is located in the second touch control conduction layer. The touch control line located in the non-display area NA adopts a double-layer conductive design, that is, the touch control line includes a first portion and a second portion connected to each other. The first portion is located in the first touch control conduction layer and the second portion is located in the second touch control conduction layer. In one embodiment, the functional structure 60 includes a first electrode block 02-1 and a second electrode block 02-2, that is, the conductive structure 20 is located in the first touch control conduction layer, and the conductive structure 20 is fabricated in the same process as the first electrode block 02-1 and the second electrode block 02-2.

In another embodiment, the functional structure 60 includes one of the first connection part and the second connection part, and the functional structure 60 is located in the second touch control conduction layer.

In some embodiments, both the first touch control conduction layer and the second touch control conduction layer include metal materials.

In some embodiments, both the first touch control conduction layer and the second touch control conduction layer include a transparent conductive material, such as indium tin oxide.

In some embodiments, FIG. 16 is a schematic diagram of another display panel according to an embodiment of the present disclosure, as shown in FIG. 16. The display panel comprises a first touch control line 85 and the second touch control line 86, the first touch control line 85 is connected to the first touch control electrode 021, and the second touch control line is connected to the second touch control electrode 022. A warning line 87 is also set on a periphery of the touch control line, and the warning line 87 access a constant voltage signal. The warning line 87 is used to shield the signal, so as to avoid interference of the external electrical signal on the touch control line. The conductive structure 20 is connected to the warning line 87 which is a metal wire, and the warning line 87 can be used to conduct and disperse the electrostatic charge on the conductive structure 20 to prevent local accumulation of electrostatic charge, thereby improving the illumination phenomenon at the edge of the display area.

In some embodiments, the periphery of the touch control line is also provided with a grounding wire, and the conductive structure 20 is configured to be connected to the grounding wire. The grounding wire can be used to conduct and disperse the electrostatic charge on the conductive structure 20, so as to prevent the local accumulation of electrostatic charge and improve the illumination phenomenon at the edge of the display area. Related figures for illustration are omitted here.

In some embodiments, FIG. 17 is a schematic diagram of another display panel according to an embodiment of the present disclosure, as shown in FIG. 17, the touch control layer 020 includes third touch control electrodes 023 arranged in an array within the display area AA, the third touch control line 024 is also arranged in the display area AA, and the third touch control line 024 is connected to the third touch control electrode 023. The touch control layer 020 includes the third touch control conduction layer and the fourth touch control conduction layer. The third touch control electrode 023 is located in the third touch control conduction layer, and the third touch control line 024 is located in the fourth touch control conduction layer. In an embodiment, both the third touch control conduction layer and the fourth touch control conduction layer include transparent conductive materials.

In an embodiment, the functional structure 60 comprises a third touch control electrode 023, the conductive structure 20 is located in the third touch control conduction layer, and the conductive structure 20 and the third touch control electrode 023 are fabricated in the same process.

In another embodiment, the functional structure 60 comprises a third touch control line 024, the conductive structure 20 is located in the fourth touch control conduction layer, and the conductive structure 20 and the third touch control line 024 are fabricated in the same process.

In some embodiments, array layer 40 includes functional structure 60, and the conductive structure 20 and the functional structure 60 in the array layer 40 are fabricated in the same layer and made of the same materials. In an embodiment, the material of the conductive structure 20 includes metal materials. As described in the embodiment of FIG. 6 above, the array layer 40 of the display panel includes metal layers. The conductive structure 20 can be fabricated by reusing any metal layer in the array layer 40.

The conductive structure 20 is configured to include a metal material, at least part of the cutting edge B of the substrate 30 overlaps the metal material along the direction perpendicular to the plane of the substrate 30, in other words, at least part of the cutting edge B of substrate 30 is covered with metal material, and the metal material has excellent electrical conductivity, such that can increase the electrostatic charge transmission path at position of the cutting edge B to avoid the accumulation of electrostatic charge at position B of the cutting edge.

In some embodiments, as shown in FIG. 2, FIG. 4, or FIG. 5, the conductive structure 20 is in contact with the surface of substrate 30 at least at an end away from the display area AA. In other words, there is no insulating layer in an edge area of substrate 30, and the insulating layer in array layer 40 does not extend to the cutting edge B of substrate 30. That is the edge of the insulating layer in the array layer 40 is not flush with the cutting edge B of the substrate 30.

Removing the insulation layer at position B of the cutting edge can reduce a cutting thickness during a cutting process. In this embodiment, the substrate 30 and conductive structure 20 may be cut when cutting the display panel along a preset cutting line, which requires low cutting energy requirement, and improves cutting accuracy.

In some embodiments, as shown in FIG. 4, the array layer 40 includes insulating layers 42, and the edge of each insulating layer 42 in the non-display area NA is not flush with the cutting edge of the substrate 30. As shown in FIG. 4, the edge of each insulating layer 42 in the non-display area NA is located on a side of the conductive structure 20 adjacent to the display area AA. In other words, the insulation layer 42 located in the edge area of the display panel is removed in the non-display area NA. When the display panel is cut along the preset cutting line, the insulation layer 42 may not be cut, which can reduce the cutting thickness during the cutting process. In addition, in this embodiment, all the conductive structure 20 are in contact with the surface of the substrate 30, and the conductive structure 20 is fabricated on a relatively flat surface to ensure the continuity of the overall conductive structure 20. Moreover, the contact area between the conductive structure 20 and the substrate 30 is relatively large, which ensures that the charge entering the substrate 30 can be quickly transferred into the conductive structure 20.

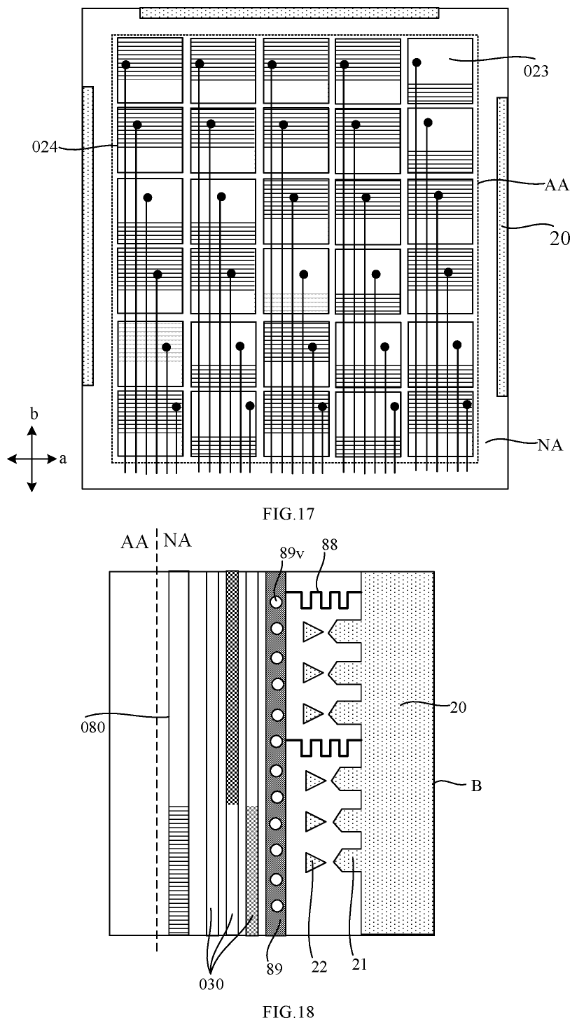

In some embodiments, FIG. 18 is a partial schematic diagram of another display panel according to an embodiment of the present disclosure, as shown in FIG. 18, an end of the conductive structure 20 adjacent to the display area AA includes a first tip structure 21, the display panel further includes a second tip structure 22 located in the non-display area NA, and a tip of the first tip structure 21 is opposite to a tip of the second tip structure 22. The shape of conductive structure 20 can be designed. As the first tip structure 21 can accumulate the electrostatic charge generated at the edge of the display panel, and the tip of the first tip structure 21 and the tip of the second tip structure 22 are configured to be opposite to each other, such that the electrostatic charge can be released to the second tip structure 22. The second tip structure 22 is made of metal materials. In an embodiment, the material of the second tip structure 22 is set to be the same as that of the conductive structure 20, and the second tip structure 22 is floating, which can avoid breakdown of an effective circuit when the electrostatic charge is released. In addition, the conductive structure 20 is connected to the grounding wire 89 through a connecting wire 88 to realize the grounding of the conductive structure 20, then the electrostatic charge entering the conductive structure 20 can be transmitted to the grounding wire 89 through connecting wire 88 and conducted away, which avoids accumulation or aggregation of electrostatic charge on the conductive structure 20.

In some embodiments, as shown in FIG. 18, the grounding wire 89 has an opening 89V that penetrates through the ground wire 89 in a direction perpendicular to the plane of the substrate 30.

In addition, as shown in FIG. 18, the non-display area NA is not only provided with the grounding wire 89, but also provided with the crack prevention groove 030 and the barrier wall 080. The crack prevention groove 030 is located at a side of the grounding wire 89 adjacent to the display area AA. The number of crack prevention groove 030 is only indicative and does not limit the present disclosure. The crack prevention groove 030 is used to prevent the crack on the insulating layer from extending to the display area AA, which also prevents undesirable phenomena, such as the crack causing the breakage of the wiring. The barrier wall 080 is used to limit the edge of the encapsulation layer of the display panel, and can be understood in conjunction with the embodiment of FIG. 11 as the second barrier wall 95 indicated in the embodiment of FIG. 11 above.

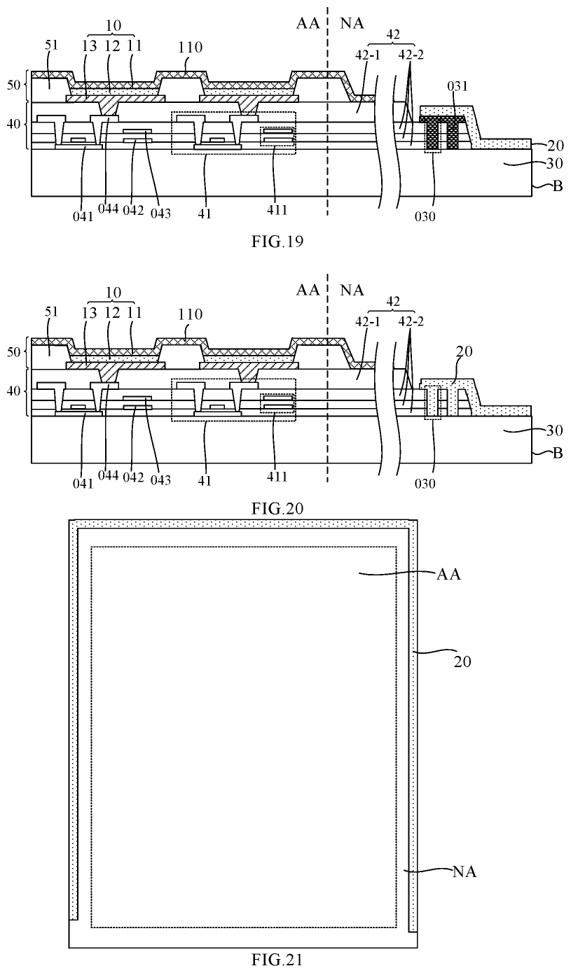

In some embodiments, FIG. 19 is another cross-sectional diagram at line A-A′ in FIG. 1. As shown in FIG. 19, the display panel includes crack prevention groove 030 located in the non-display area NA; In the direction e perpendicular to the plane of the substrate 30, at least part of the conductive structure 20 overlaps the crack prevention groove 030. In the embodiment of the present disclosure, at least part of the edge of the side of conductive structure 20 away from the display area AA is flush with the cutting edge B of the substrate 30, and at least part of the edge of the side of conductive structure 20 adjacent to the display area AA overlaps crack prevention groove 030, that is, conductive structure 20 extends from the cutting edge B of substrate 30 towards the display area AA to the crack prevention groove 030, such that the conductive structure 20 in the non-display area NA has a large width, and has larger area correspondingly, which prevents electrostatic charge from accumulating at the cutting edge of the substrate 30 and not dissipating and affecting pixels adjacent to the cutting edge B, thereby improving the illumination phenomenon at the edge of the display area.

As shown in FIG. 19, the array layer 40 includes a semiconductor layer 041, a first metal layer 042, a second metal layer 043 and a third metal layer 044. The insulating layers set between the semiconductor layer 041 and the first metal layer 042, between the first metal layer 042 and the second metal layer 043, and between the second metal layer 043 and the third metal layer 044 are all inorganic insulating layers 42-2; and an organic insulation layer 42-1 is also disposed on a side of the third metal layer 044 away from the substrate 30. Both the inorganic insulating layer 42-2 and organic insulating layer 42-1 belong to the insulating layer 42 in the array layer 40. The crack prevention groove 030 penetrates through the inorganic insulating layer 42-2 in the array layer 40.

Only two crack prevention grooves 030 are shown schematically in FIG. 19, but the number of the crack prevention groove 030 is not limited in the embodiment of the present disclosure.

As shown in FIG. 19, the crack prevention groove 030 is filled with filling medium 0310, and the conductive structure 20 is in contact with the filling medium 031 on a side of filling medium 031 away from the substrate 30. As shown in FIG. 19, the edges of each insulating layer 42 in the array layer 40 in the non-display area NA are not flush with the cutting edge B of the substrate 30. The conductive structure 20 covers an edge slope formed by the inorganic insulating layer 42-2 and extends to a side of the filling medium 031 away from the substrate 30 to contact the filling medium 031. The conductive structure 20 extends from the cutting edge B of the substrate 30 towards the display area AA to arrive at the crack prevention groove 030, such that the conductive structure 20 set in the non-display area NA has a large width, and then the conductive structure 20 has a large area correspondingly, such that an overall resistance of the conductive structure 20 is relatively low.

In another embodiment, an edge of the inorganic insulating layer 42-2 in the array layer 40 is flush with the cutting edge B of the substrate 30. In a direction e perpendicular to the plane of the substrate 30, at least part of the conductive structure 20 overlaps crack prevention groove 030, and related figures for illustration are omitted.

In some embodiments, the filling medium 031 in the crack prevention groove 030 includes organic materials.

In some embodiments, the filling medium 031 in the crack prevention groove 030 includes metal materials. In this embodiment, when the display panel is cut along the preset cutting line, the metal materials deposited in the crack prevention groove 030 can be used as an auxiliary alignment mark, and the metal material deposited in crack prevention groove 030 can be used to match the auxiliary alignment mark to achieve cutting alignment.

In some embodiments, FIG. 20 is another cross-sectional diagram at line A-A′ in FIG. 1. As shown in FIG. 20, part of the conductive structure 20 is filled in the crack prevention groove 030. This setting can increase the area of conductive structure 20, decrease the resistance of conductive structure 20, and the charge can be quickly conducted into the conductive structure 20, which can prevent electrostatic charge from accumulating at the cutting edge of the substrate 30 and not dissipating and affecting pixels adjacent to the cutting edge B, thereby improving the illumination phenomenon at the edge of the display area.

In another embodiment, FIG. 21 is a schematic diagram of another display panel according to an embodiment of the present disclosure, as shown in FIG. 21, the conductive structure 20 is configured to surround half of the display area AA, and the conductive structure 20 in the non-display area NA is a continuous structure. Such setting can ensure that the conductive structure 20 can be used to shield the electrostatic charge at the cutting edge of the substrate 30 in different directions, prevent electrostatic charge from entering the substrate 30 through the cutting edge of the substrate 30, and then prevent electrostatic charge from accumulating at the cutting edge of the substrate 30 and not dissipating and affecting pixels adjacent to the cutting edge B, thereby improving the illumination phenomenon at the edge of the display area.

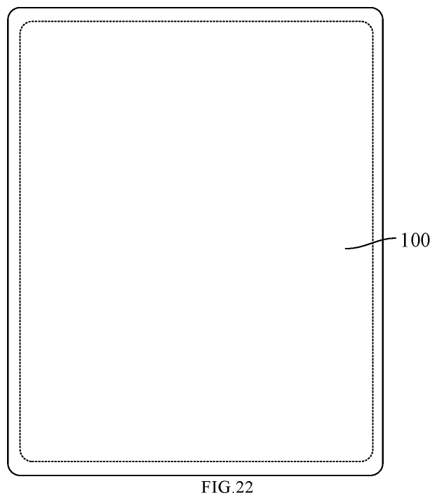

Based on the idea of the same application, the embodiment of the present disclosure also provides a display device. FIG. 22 is a schematic diagram of a display device according to an embodiment of the present disclosure. As shown in FIG. 22, the display device includes a display panel 100 provided by any embodiment of the present disclosure. The structure of the display panel 100 is described in the above embodiments and will not be repeated here. The display device provided by an embodiment of the present disclosure includes any other device with a display function, such as a mobile phone, a tablet computer, a laptop computer, a television set, a smart watch.

The above description merely illustrates some embodiments of the present disclosure, and is not intended to limit the present disclosure. Any modifications, equivalent replacements, improvements, and the like made within the principle of the present disclosure shall fall within the protection scope of the present disclosure.

Finally, it should be noted that the foregoing embodiments are merely intended to describe and not to limit the technical solutions of the present disclosure. Although the present disclosure has been described in detail with reference to the foregoing embodiments, persons skilled in the art should understand that they can still make modifications to the technical solutions described in the foregoing embodiments or make equivalent replacements to some or all of the technical features thereof. These modifications or replacements do not make the essence of the corresponding technical solutions deviate from the scope of the technical solutions of the embodiments of the present disclosure.

What is claimed is:

1. A display panel comprising:
a display area;
a non-display area;
a substrate; and
a conductive structure located on a side of the substrate, wherein the conductive structure is located in the non-display area; and
at least part of an edge of the conductive structure away from the display area overlaps a cutting edge of the substrate in a direction perpendicular to a plane of the substrate.

2. The display panel according to claim 1, comprising a functional structure located on a same side of the substrate as the conductive structure, wherein at least part of the functional structure is located in the display area, and
the conductive structure and the functional structure are made of a same material.

3. The display panel according to claim 2, wherein the conductive structure and the functional structure are not connected to each other.

4. The display panel according to claim 1, further comprising:
a plurality of light emitting devices located on a side of the substrate in the display area, wherein one light emitting device of the plurality of light emitting devices comprises:
a first electrode, and
a light emitting layer and a second electrode that are stacked, and first electrodes of the light emitting devices are connected to each other to form a first electrode layer, wherein the first electrode layer extends from the display area to the non-display area; and wherein the functional structure comprises the first electrode layer.

5. The display panel according to claim 4, wherein
the non-display area is provided with a partition structure, and
the conductive structure and the first electrode layer are disconnected at a position of the partition structure.

6. The display panel according to claim 5, wherein
the partition structure comprises a first metal portion, and an end of the first metal portion adjacent to the display area is in contact with the first electrode layer, and
another end of the first metal portion away from the display area is in contact with the conductive structure.

7. The display panel according to claim 6, wherein
the partition structure further comprises a second metal portion and a middle portion, the middle portion is located on a side of the first metal portion away from the substrate, the second metal portion is located on a side of the middle portion away from the first metal portion, and the second metal portion extends out of an edge of the middle portion to form a step.

8. The display panel according to claim 5, wherein
the partition structure comprises a groove having a groove bottom and a notch; and
a length of the notch is less than a length of the groove bottom in a direction from the display area to the cutting edge.

9. The display panel according to claim 8, wherein the groove is located at the substrate.

10. The display panel according to claim 8, wherein
a metal wire is located on a side of the groove away from the display area; and
the conductive structure is connected to the metal wire.

11. The display panel according to claim 10, wherein
the metal wire is floating, or the metal wire is connected to a fixed potential.

12. The display panel according to claim 5 comprising an encapsulation layer, wherein the encapsulation layer is located on a side of the light emitting device away from the substrate, and an edge of the encapsulation layer is located in the non-display area; and
the partition structure is located on a side of the edge of the encapsulation layer away from the display area.

13. The display panel according to claim 4, further comprising:
a power structure located in the non-display area, wherein an edge of the first electrode layer is connected to the power structure located in the same layer as the second electrode; and
an end of the conductive structure adjacent to the display area is connected to the power structure.

14. The display panel according to claim 4, wherein
the non-display area is provided with a metal wire, and the metal wire is arranged to surround at least half of the display area; and
the conductive structure is connected to the metal wire.

15. The display panel according to claim 2, further comprising a touch control layer, wherein the touch control layer comprises the functional structure.

16. The display panel according to claim 1, wherein
the non-display area is provided with a constant voltage terminal, and the conductive structure is connected to the constant voltage terminal.

17. The display panel according to claim 1, wherein
at least an end of the conductive structure away from the display area is in contact with a surface of the substrate.

18. The display panel according to claim 1, further comprising:
an array layer located on a side of the substrate, wherein the array layer comprises pixel circuits and insulating layers; and
the insulating layer is not flush with the cutting edge of the substrate at an edge of the non-display area.

19. The display panel according to claim 1, wherein
an end of the conductive structure adjacent to the display area comprises a first tip structure; and
the display panel further comprises a second tip structure located in the non-display area, and a tip of the first tip structure and a tip of the second tip structure are opposite to each other.

20. The display panel according to claim 1, further comprising a crack prevention groove located in the non-display area;
wherein at least part of the conductive structure overlaps the crack prevention groove in the direction perpendicular to the plane of the substrate.

21. The display panel according to claim 20, wherein the crack prevention groove is filled with a filling medium, and the conductive structure is in contact with the filling medium at a side of the filling medium away from the substrate.

22. The display panel according to claim 21, wherein
the filling medium comprises at least one of an organic material or a metal material.

23. The display panel according to claim 20, wherein
part of the conductive structure is filled in the crack prevention groove.

24. The display panel according to claim 1, wherein
the substrate comprises a first flexible substrate and a second flexible substrate that are stacked.

25. The display panel according to claim 1, wherein
the conductive structure is made of metal or metal oxide.

26. A display device comprising:
a display area;
a non-display area;
a substrate; and
a conductive structure located on one side of the substrate, wherein the conductive structure is located in the non-display area; and
at least part of an edge of the conductive structure away from the display area overlaps a cutting edge of the substrate in a direction perpendicular to a plane of the substrate.
